(19) United States
(12) Patent Application Publication
(10) Pub. No.: US 2005/0211167 A1
(43) Pub. Date: Sep. 29, 2005

(54) Processing device and processing method

(75) Inventors: Isao Gunji, Yamanashi (JP); Tadahiro Ishizaka, Yamanashi (JP); Hiroshi Kannan, Tokyo (JP); Ikuo Sawada, Yamanashi (JP); Yasuhiko Kojima, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited

(21) Appl. No.: 10/517,345

(22) PCT Filed: Jun. 9, 2003
(86) PCT No.: PCT/JP03/07294

§ 371 Date: Dec. 9, 2004

(30) Foreign Application Priority Data
Jun. 10, 2002 (JP) 2002-169322

(51) Int. Cl. C23C 16/00

(52) U.S. Cl. 118/715

(57) ABSTRACT

The ceiling surface (12b) of a chamber (12) is substantially entirely formed with a gas supply port (19). Further, the gas supply port (19) has shower head (20) fitted therein. The peripheral edge of the ceiling surface (12b) has connected thereto a second side wall (12d) forming an angle greater than 90 degrees with ceiling surface (12b). Further, the side surface of a susceptor (16) is formed such that it forms an angle greater than 90 degrees with a mounting surface for a wafer (W) and is substantially parallel with the second side wall (12d) of the chamber (12). Further, the susceptor (16) is disposed such that the distance (L2) between its side surface and the second side wall (12d) is greater than the distance (L1) between the shower head (20) and the wafer (W).

### FIELD OF THE INVENTION

The present invention relates to a processing device and method for performing a surface processing on an object to be processed such as a semiconductor wafer.

### BACKGROUND OF THE INVENTION

A recent development toward a high miniaturization and a high integration of semiconductor integrated circuits involves a miniaturization of patterns such as wiring grooves which are formed on a surface of, e.g., a substrate. Therefore, for example, in case a thin film is formed as an underlying film of a wiring metal, it is required to uniformly form a very thin film in a fine wiring groove with a good coverage. Hence, as a method for forming a film of an atomic layer level with a good film quality even in the fine groove, a so-called atomic layer deposition (ALD) method has been recently developed.

The ALD method is carried out by the following steps for example. In the following example, there will be described a case for forming, by using a titanium tetrachloride gas and an ammonia gas, an underlying film formed of a titanium nitride on a surface of a substrate in which wiring patterns (wiring groves) are formed.

First, the substrate is loaded in a chamber and inside of the the chamber is evacuated to a certain vacuum level. Next, the titanium tetrachloride gas is introduced for a predetermined time period into the chamber. As a result, molecules of titanium tetrachloride are adsorbed in multiple layers onto the surface of the substrate. Then by purging the inside of the chamber with an inert gas, the titanium tetrachloride, excepting approximately single layer of titanium tetrachloride molecules adsorbed on the substrate surface, is removed from the chamber.

After the purge, the ammonia gas is introduced for a preset time period into the chamber, so that the molecules of the ammonia gas react with the titanium tetrachloride molecules adsorbed on the surface of the substrate to form the titanium nitride layer corresponding to approximately single monatomic layer on the surface of the substrate. At this time, multiple layers of ammonia molecules are formed on the formed titanium nitride layer. Then, the inside of the chamber is purged with an inert gas, so that the ammonia molecules, excepting approximately single layer of ammonia molecules adsorbed on the titanium nitride layer, are removed from the chamber.

Subsequently, the titanium tetrachloride gas is again introduced for a predetermined time period into the chamber, so that titanium tetrachloride reacts with the ammonia molecules adsorbed to form a new titanium nitride layer. That is, in this state, the titanium nitride layers corresponding to approximately two monatomic layers are formed.

Further, at this time, multiple layers of titanium tetrachloride molecules are adsorbed on the titanium nitride layer. Then, by purging the inside of the chamber with an inert gas, there remains an approximately single layer of titanium tetrachloride adsorbed on the titanium nitride layers. Thereafter, by changing the atmosphere inside the chamber as described above by performing the introduction of the ammonia gas, the purge, the introduction of the titanium tetrachloride gas, the purge, . . . , the titanium nitride layer is formed in a predetermined number of monatomic layers, i.e., a predetermined thickness. For example, by changing the atmosphere inside the chamber several hundreds to several thousands times, it is possible to form a titanium nitride film of several nm to several tens of nm. Accordingly, in order to achieve a high throughput by using the ALD method, it is required to carry out the change of the gas atmosphere in a highly expeditious manner.

Conventionally, the aforementioned ALD process is carried out by using a processing device shown in FIG. 8. The processing device shown in the drawing includes a cylindrical chamber 102; a disc-shaped susceptor 104, for mounting thereon a semiconductor wafer W, fixed through a shaft 103 at an approximately central portion of the chamber 102; a gas supply port 105 provided at a top portion of the chamber 102; and a gas exhaust port 106 provided at a bottom portion of the chamber 102.

When a gas flows in the chamber 102 constructed as described above, a stationary gas flow, i.e., so called stagnation of gas, is likely to be established at locations R1 and R2 near the gas supply port 105 and the susceptor 104 in the chamber 102. This is also likely to occur at locations R3 and R4 under the susceptor 104 and near the gas exhaust port 106. In the area wherein the stagnation of gas has occurred, the gas flow becomes nonuniform. Therefore, the gas change is hard to be carried out in the areas where the stagnation of gas has occurred compared with the other areas. As a result, as the stagnation occurrence area becomes larger, the speed of changing the atmosphere in the chamber 102 is reduced to thereby decrease the throughput.

As described above, the conventional processing device employed in the ALD method suffers from a drawback that, due to the occurrence of the stagnation of gas, the gas atmosphere changing speed is decreased, failing to obtain a sufficiently high productivity.

### SUMMARY OF THE INVENTION

It is, therefore, an object of the present invention to provide a highly productive processing device and method capable of changing a gas atmosphere at a high speed.

In accordance with a first aspect of the present invention for accomplishing the above-described object, there is provided a processing device including:
a chamber;
a mounting table, disposed in the chamber, for mounting thereon an object to be processed; and
a gas supply port for supplying a gas into the chamber, the gas supply port being provided at a surface of the chamber;
wherein the mounting table is disposed substantially parallel to the surface of the chamber; and
in a substantially vertical cross section of the chamber taken along a flow of the gas from the gas supply port toward the object to be processed, a sidewall of the chamber abutting on the surface of the chamber forms an angle greater than 90° with the surface of the chamber.

According to the above configuration, the stagnation of gas near the gas supply port is suppressed so that a sufficient change of a gas atmosphere can be carried out in a short time. Therefore, the change of atmosphere can be made at a high speed, thereby resulting in an increased productivity.

Preferably, the gas supply port is configured to have a substantially same area as that of the object to be processed.

Further, it is preferable that, in a substantially vertical cross section of the mounting table taken along the flow of the gas from the gas supply port toward the object to be processed, a mounting surface on which the object to be processed is mounted forms an angle greater than 90° with a side surface of the mounting table abutting on the mounting surface.

Moreover, it is preferable that, in a substantially vertical cross section of the chamber and the mounting table taken along the flow of the gas from the gas supply port toward the object to be processed, the sidewall of the chamber is configured to be substantially parallel to the side surface of the mounting table.

In addition, it is preferable that, in a substantially vertical cross section of the chamber and the mounting table taken along the flow of the gas from the gas supply port toward the object to be processed, the distance between the sidewall of the chamber and the side surface of the mounting table is set to be less than the distance between the surface of the chamber and the object to be processed.

In accordance with a second aspect of the present invention for accomplishing the above-described object, there is provided a processing device including:
a chamber;
a mounting table, disposed in the chamber, for mounting thereon an object to be processed; and
a gas supply port for supplying a gas into the chamber, the gas supply port being provided at a surface of the chamber;
wherein the mounting table is disposed substantially parallel to the flow direction of the gas supplied from the gas supply port; and
in a substantially vertical cross section and/or a substantially horizontal cross section of the chamber, a sidewall of the chamber abutting on the surface of the chamber forms an angle greater than 90° with the surface of the chamber.

In accordance with a third aspect of the present invention for accomplishing the above-described object, there is provided a processing device including:
a chamber;
a mounting table, disposed in the chamber, for mounting thereon an object to be processed;
a gas supply port for supplying a gas into the chamber, the gas supply port being provided at a surface of the chamber; and
a gas exhaust port for evacuating the chamber;
wherein the chamber is constructed such that a cross sectional area of a flow passageway along which the gas supplied from the gas supply port flows to reach a vicinity of the object to be processed is gradually increased as the gas flows therealong and a cross sectional area of a flow passageway along which the gas reaches the gas exhaust port after passing through the vicinity of the object to be processed is gradually decreased as the gas flows therealong.

According to the above configurations, the stagnation of gas near the gas exhaust port as well as the gas supply port is suppressed so that a sufficient change of a gas atmosphere can be carried out in a shorter time.

In accordance with a fourth aspect of the present invention for accomplishing the above-described object, there is provided a method for processing a substrate disposed in a chamber while changing an atmosphere in the chamber by alternately supplying a plurality of gas species from a gas supply port into the chamber, the method including:
a gas supply step for supplying a gas from the gas supply port into the chamber; and
a speed change step for gradually increasing a speed of the gas after passing through a vicinity of the substrate with respect to a speed of the gas passing the vicinity of the substrate along a flow direction of the gas supplied in the gas supply step.

According to the above method, since there is increased a gas speed near the sidewall of the chamber at a downstream side where the stagnation of gas is likely to occur, the occurrence of the stagnation of gas can be effectively suppressed. Therefore, the atmosphere change can be made at a high speed, thereby resulting in an increased productivity.

Preferably, at the speed change step, a cross sectional area of a flow passageway of the gas after passing through the vicinity of the substrate is smaller than that of a flow passageway of the gas passing through the vicinity of the substrate in the chamber.

### BRIEF DESCRIPTION OF THE DRAWINGS

FIG. 1 shows a vertically cross sectional view of a processing device in accordance with an preferred embodiment of the present invention;

FIG. 2 illustrates a flowchart of a film forming process using the processing device in accordance with the preferred embodiment of the present invention.;

FIG. 3A schematically describes a simulation result of a pressure distribution in a case wherein the processing device shown in FIG. 1 is employed;

FIG. 3B schematically sets forth a simulation result of a pressure distribution in a case wherein a conventional processing device is employed;

FIG. 4 depicts a vertically cross sectional view of a processing device in accordance with another preferred embodiment of the present invention;

FIG. 5 provides a horizontally cross sectional view of a processing device in accordance with still another preferred embodiment of the present invention;

FIG. 6 presents a vertically cross sectional view of a processing device in accordance with still further another preferred embodiment of the present invention;

FIG. 7 represents a vertically cross sectional view of a processing device showing a modification of the preferred embodiment of the present invention; and

FIG. 8 schematically illustrates stagnation occurrence areas in the conventional processing device.

### DETAILED DESCRIPTION OF THE PREFERRED EMBODIMENTS

A processing device in accordance with preferred embodiments of the present invention will now be described with reference to the drawings. In the preferred embodiments, there are described as examples processing devices wherein a titanium tetrachloride (TiCl₄) gas and an ammonia (NH₃) gas are alternately supplied into a chamber with a purge by an argon (Ar) gas being carried out therebetween to form a titanium nitride (TiN) film on a surface of a semiconductor wafer (referred to as a wafer W, hereinafter) by using a so-called atomic layer deposition (ALD) method.

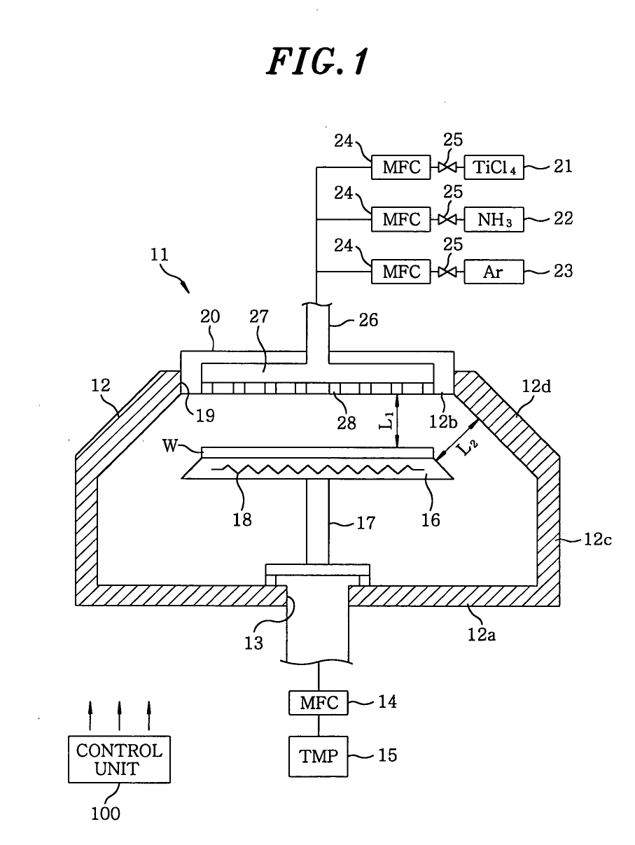

FIG. 1 shows a vertically cross sectional side view of a processing device 11 in accordance with a preferred embodiment of the present invention. As indicated in FIG. 1, the processing device 11 includes a hollow cylindrical chamber 12 having an approximately hexagonal cross sectional shape. The chamber 12 is formed of, e.g., stainless steel, aluminum or the like.

A gas supply unit 28 is provided in a gas supply port 19. The gas supply unit 28 is connected with a TiCl₄ gas source 21, an NH₃ gas source 22 and an Ar gas source 23 via respective mass flow controllers 24 and valves 25.

As shown in FIG. 1, the chamber 12 includes a bottom surface 12a; a ceiling surface 12b approximately horizontally extending parallel to the bottom surface 12a, the ceiling surface 12b having a smaller diameter than that of the bottom surface 12a; a first sidewall 12c extending upright from the bottom surface 12a; and a second sidewall 12d connecting the first sidewall 12c and the ceiling surface 12b, the second sidewall 12d forming an angle greater than 90° with the ceiling surface 12b.

A gas exhaust port 13 is provided at the bottom surface 12a of the chamber 12. The gas exhaust port 13 is connected to a gas exhaust unit 15 through a pressure control device 14 such as an APC (Automatic Pressure Controller). The gas exhaust unit 15 includes, e.g., a TMP (Turbo Molecular Pump) and evacuates the chamber 12 to decrease the pressure therein.

A disc-shaped susceptor 16 is installed approximately at the center of the chamber 12. The susceptor 16 is supported by a shaft 17 fixed to the bottom surface 12a of the chamber 12. On the top surface of the susceptor 16, a wafer W serving as an object to be processed is mounted.

The top surface of the susceptor 16 has a larger diameter than that of the wafer W. A heater 18 formed of, e.g., a resistance heating material is embedded in the susceptor 16 for heating the wafer W on the susceptor 16.

As shown in FIG. 1, the susceptor 16 has a trapezoidal cross section when viewed in a direction parallel to a main surface (a direction perpendicular to the paper surface). The diameter of a bottom surface of the susceptor 16 is set to be greater than that of the top surface; and thus a peripheral edge portion (side surface) of the susceptor 16 forms an angle greater than 90° with the wafer mounting surface. Herein, the susceptor 16 is configured to support the wafer W at a substantially identical to the height of the first sidewall 12c, i.e., the height of the contact portion between the second sidewall 12d and the first sidewall 12c. For example, the susceptor 16 is formed such that the bottom surface thereof is located at an approximately same level as the height of the first sidewall 12c. Further, the side surface of the susceptor 16 having a taper configuration is formed to approximately parallel to the second sidewall 12d.

The gas supply port 19 is provided at the ceiling surface 12b of the chamber 12 such that it faces the gas exhaust port 13 with the susceptor 16 disposed therebetween. The gas supply port 19 is set to have an approximately same area as that of the wafer W.

A shower head 20 is fitted in the gas supply port 19. The shower head 20 includes a gas supply pipe 26 which is connected to the TiCl₄ gas source 21, the NH₃ gas source 22 and the Ar gas source 23 via the respective flow rate controlling devices 24, e.g., MFC (Mass Flow Controller), and valves 25. The gas supply pipe 26 is connected to a hollow diffusion portion 27 provided in the shower head 20.

The shower head 20 has, at its surface exposed to the inside of the chamber 12, a plurality of gas supply openings 28 communicating with the diffusion portion 27. Gases, fed into the shower head 20 from the respective gas sources 21 to 23, are diffused in the diffusion portion 27 and ejected from the gas supply openings 28. Here, by the diffusion portion 27, the gases are supplied from the gas supply openings 28 in a substantially uniform manner.

The gas supply openings 28 are provided substantially throughout the exposed surface of the shower head 20. The shower head 20 is constructed to have a larger diameter than that of the wafer W so that the gases are supplied to the entire surface of the wafer W.

Since the ceiling surface 12b is configured to substantially entirely overlap with the gas supply port 19, the gases are supplied from almost all over the ceiling surface 12b. Here, the second sidewall 12d of the chamber 12 is constructed to form an angle greater than 90° with the abutting ceiling surface 12b.

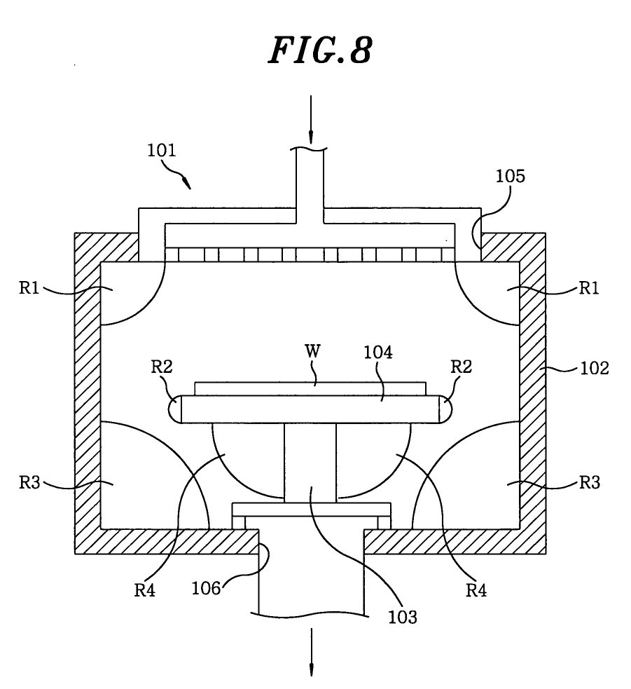

In case of a structure without such a configuration of the chamber 12, when a gas is supplied, stagnation of gas is likely to occur at location R1 near the gas supply port as shown in FIG. 8. Since, however, an area near the gas supply port 19 at which the stagnation of gas is likely to occur is physically excluded in the chamber with the configuration shown in FIG. 1, occurrence of the gas stagnation is decreased.

Further, since the susceptor 16 is formed to have a generally trapezoidal cross section, area (R2 in FIG. 8) near the side of the susceptor 16 at which the gas stagnation is apt to occur is physically excluded, so that the occurrence of gas stagnation is decreased.

Moreover, as shown in FIG. 1, the distance L₂ between the side surface of the susceptor 16 and the sidewall 12d of the chamber 12 is less than the distance L₁ between the shower head 20 and the wafer W. That is, after passing the wafer W, the gas supplied from the shower head 20 flows through a flow passageway with a cross sectional area less than that of a flow passageway along which the gas flows on the wafer W. As a result, the gas flows at an increased speed along the sidewalls 12d and 12c, so that the occurrence of gas stagnation (R3 in FIG. 8) at a lower portion of the chamber 12 can be effectively suppressed.

The control unit 100 controls operations of the respective components of the processing device having the above-described configuration. Further, the control unit 100 stores therein a processing sequence for performing a predetermined process and carries out the following process based on the processing sequence. Herein, descriptions on the configuration of the control unit 100 and detailed operations thereof will be omitted.

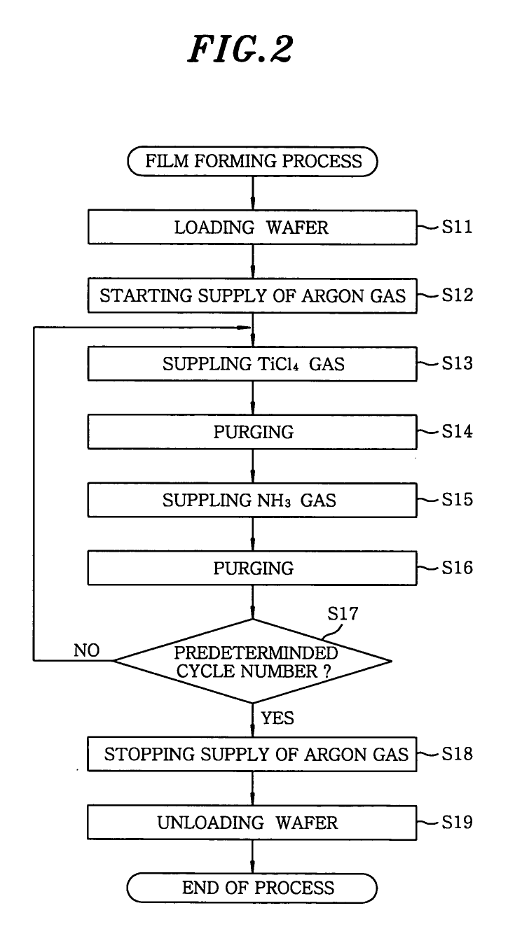

Hereinafter, a method for forming a TiN film on the surface of the wafer W by using the processing device 11 constructed as mentioned above will be described with reference to FIG. 2. FIG. 2 is a flowchart showing the TiN film forming method in accordance with the preferred embodiment of the present invention. Further, the flowchart shown in FIG. 2 is an example of the processing and the processing is not limited to the sequence indicated in the flowchart as long as the same product can be obtained.

First, e.g., a transfer arm (not shown) is operated to load a wafer W in the chamber 12 and mount it on a mounting table 16 (step S11) . Next, the heater 18 in the susceptor 16 is controlled to heat the wafer W to a predetermined temperature, e.g., 450° C. and, at the same time, an Ar gas is supplied into the chamber 12 (step S12). At this time, the Ar gas is controlled to be supplied at a flow rate of, e.g., 200 sccm and the pressure of the chamber 12 is maintained at, e.g., 400 Pa (3 Torr). Further, the Ar gas continuously flows in the chamber 12 during the process described below.

Subsequently, a TiCl₄ gas is supplied for a predetermined time period, e.g., 0.5 sec, into the chamber 12 (step S13). At this time, the TiCl₄ gas is controlled to be supplied at a flow rate of, e.g., 30 sccm, so that TiCl₄ molecules are adsorbed onto the surface of the wafer W.

After a predetermined time period, the supply of the TiCl₄ gas is stopped. Under this condition, since the Ar gas still flows, the inside of the chamber 12 is purged with the Ar gas (step S14). At this time, the TiCl₄ gas (molecules), excepting approximately one monatomic layer of TiCl₄ molecules adsorbed on the surface of the wafer W, are pumped out and removed from the chamber 12.

Then, after the purge for a predetermined time period, e.g., 0.5 sec, an NH₃ gas is supplied into the chamber 12 for a predetermined time period, e.g., 0.5 sec (step S15). The NH₃ gas is controlled to be supplied at a flow rate of, e.g., 50 sccm.

At this time, the NH₃ molecules react with the TiCl₄ molecules adsorbed on the surface of the wafer W to form a TiN layer corresponding to approximately one monatomic layer. Further, the NH₃ molecules are adsorbed onto the TiN layer thus formed.

After a predetermined time period, the NH₃ gas supply is stopped. Under this condition, since the Ar gas still flows, the inside of the chamber 12 is purged with the Ar gas (step S16). At this time, the NH₃ molecules in the chamber 12, excepting approximately one layer of NH₃ molecules adsorbed on the TiN layer, are pumped out and removed from the chamber 12.

After the purge for a predetermined time period, e.g., 0.5 sec, the process returns to step S13 and the TiCl₄ gas is supplied in the chamber 12. At this time, the TiCl₄ molecules react with the NH₃ molecules on the TiN layer to form a new TiN layer corresponding to approximately one monatomic layer. Further, the TiCl₄ molecules are adsorbed onto the TiN layer.

After supplying the TiCl₄ gas, the purge by the Ar gas is performed (step S14), so that the TiCl₄ molecules, excepting approximately one monatomic layer of TiCl₄ molecules adsorbed on the TiN layer, are pumped out and removed from the chamber 12.

Subsequently, the NH₃ gas is supplied in the chamber 12 (step S15), so that the NH₃ molecules react with the TiCl₄ molecules adsorbed on the TiN layer to form a new TiN layer. Further, the NH₃ melecules are adsorbed onto the TiN layer.

After supplying the NH₃ gas, the purge by the Ar gas is performed (step 16), so that the NH₃ molecules, excepting approximately one monatomic layer of NH₃ molecules adsorbed on the TiN layer are pumped out and removed from the chamber 12.

Thereafter, as described above, steps S13 to S16 are repeated, so that the TiN layers are laminated by approximately one monatomic layer at a time. By repeating the above process by a predetermined number of times, the Ti layer of a predetermined thickness is formed. The control unit 100 stores therein a number of iterations required to form a TiN layer of the predetermined thickness.

At step S17, the control unit 100 determines whether or not the process of steps S13 to S16 has been repeated by the required number of times. If it is determined that the process has not reached the required number of times (step S17: NO), the process returns to step S13 and is repeated. If it is determined that the process has reached the required number of times (step S17: YES), the supply of the Ar gas is stopped (step S18). Subsequently, the wafer W is unloaded out of the chamber 12 by, e.g., the transfer arm (step S19) and the film forming process is completed.

In the aforementioned ALD process, the change of the gas atmosphere in the chamber 12 is performed by several times. As described above, the chamber 12 in accordance with the preferred embodiment of the present invention has the structure capable of suppressing the occurrence of gas stagnation at the locations near the gas supply port 19 and the susceptor 16 and at the lower portion of the chamber 12. The occurrence of gas stagnation increases the overall residence time of the gas in the chamber 12; and the gas in the stagnation areas is not easily changed, thereby decreasing the changing speed of the gas atmosphere. However, in accordance of the preferred embodiment of the present invention, the change of the atmosphere in the chamber 12 becomes easy, so that the gas change is performed at a high speed.

Further, since the areas at which the stagnation of gas occurs are excluded, the inner volume of the chamber 12 is substantially reduced. Accordingly, it is possible to perform a change of the atmosphere in the chamber 12 at a higher speed.

### EXAMPLE

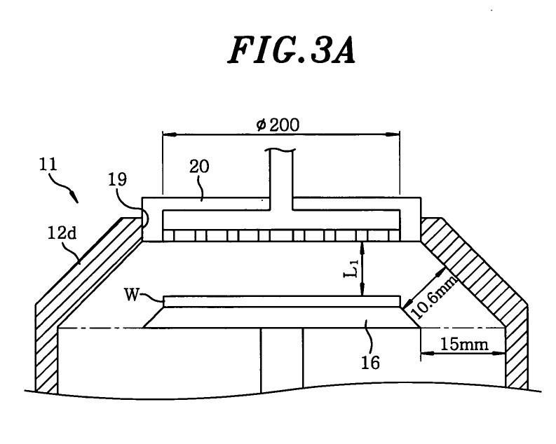

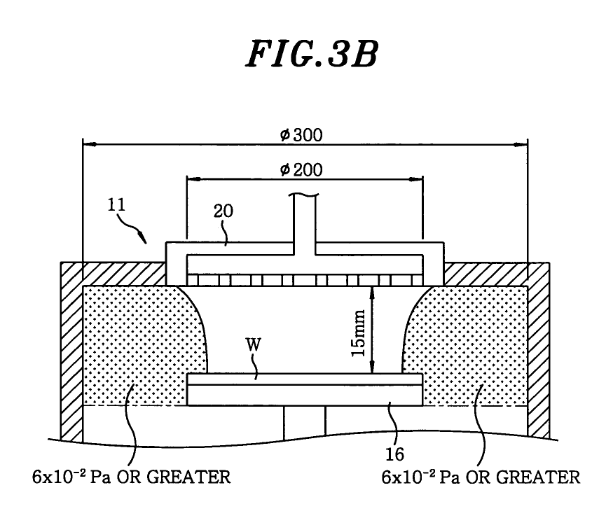

FIG. 3A illustrates a simulation result of a pressure distribution of the gas in the processing device shown in FIG. 1 in accordance with the preferred embodiment of the present invention. Further, FIG. 3B indicates a result of a case wherein a conventional chamber 12′ is employed (Comparison Example). The conditions of the simulation are as follows:

### Preferred Embodiment of the Present Invention

Diameter of the wafer W: 200 mm

Maximum diameter of gas supply: 200 mm

Distance L₁ between the shower head 20 and the wafer W: 15 mm

Distance L₂ between the side surface of the susceptor 16 and the second sidewall 12d of the chamber: 10.6 mm

Distance between the side surface of the susceptor 16 and the first sidewall 12c of the chamber: 15 mm

Inner diameter of the chamber 12 below the susceptor 16: 250 mm

### Comparison Example

Diameter of a wafer W: 200 mm

Maximum diameter of gas supply: 200 mm

Distance between a shower head 20 and the wafer W: 15 mm

Inner diameter of the chamber 12: 300 mm

(Gas Supply)

While flowing the Ar gas at 1000 sccm, a TiCl₄ gas is introduced such that the total pressure becomes 399 Pa (3 Torr) under the condition of TiCl₄:Ar=3:5.

The simulation was performed on an upper region of the chamber 12 above the bottom surface of the susceptor 16. Based on the above conditions, the pressure distribution in the chamber 0.3 seconds after introducing the gas was calculated. The results are shown by indicating with dots the region where the partial pressure of TiCl₄ is 6.65×10⁻² Pa (5×10⁻⁴ Torr) or greater.

In the conventional chamber 12′ having the gas stagnation occurrence regions, the region wherein the partial pressure of TiCl₄ is 6.65×10⁻² Pa or greater is formed to cover an edge portion of the susceptor 16 from the neighborhood of the gas supply port 19, as shown in FIG. 3B. On the other hand, in the preferred embodiment of the present invention shown in FIG. 3A, it is understood that a uniform pressure distribution is established in the upper area of the chamber 12 without such region shown in FIG. 3B.

From the results indicated in FIGS. 3A and 3B, it is understood that the chamber 12 of the preferred embodiment suppresses a decrease of a conductance (indicating a easiness of a gas flow as a whole) due to occurrence of a region where a pressure therein is comparatively high. Accordingly, in the chamber 12 of the preferred embodiment of the present invention, occurrence of the gas stagnation due to the decrease of the conductance is reduced.

As described above, in the processing device of the preferred embodiment of the present invention, regions near the gas supply port 19 and the susceptor 16 at which the stagnation of gas is likely to occur are physically excluded. Therefore, it is possible to avoid a decrease in a changing speed of gas atmosphere in the chamber 12 due to the occurrence of gas stagnation upon supply of the gas. Further, the volume of the chamber 12 is substantially decreased. Accordingly, it is possible to change the atmosphere in the chamber 12 at a high speed, thereby increasing the productivity.

The present invention is not limited to the preferred embodiment described above and various modifications and applications thereof may be made. Hereinafter, modifications of the preferred embodiment which are applicable to the present invention will be described.

In the above preferred embodiment, the gas is supplied via the shower head 20 into the chamber 12. Instead of the shower head 20, however, a nozzle structure may be employed.

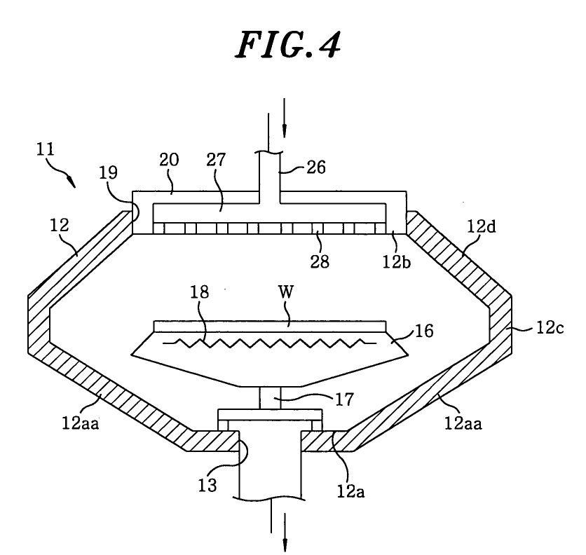

In the above preferred embodiment, eliminated in the upper portion of the chamber 12 are the regions at which the stagnation of gas is likely to occur. However, the present invention is not limited thereto; and, regions at which the stagnation of gas is likely to occur may be eliminated in the entire inner space of the chamber 12 as similarly to the above. For example, as shown in FIG. 4, the chamber 12 may have generally octagonal cross section. Further, in the lower portion of the chamber 12, the sidewall 12aa on the exhaust side is constructed to form an angle greater than 90° with the bottom surface having the gas exhaust port 13. That is, a region near the gas exhaust port 13 at which the stagnation of gas is likely to occur is physically excluded.

Moreover, in the structure shown in FIG. 4, the bottom surface of the susceptor 16 is tapered protruding toward the exhaust port 13. In this way, a region under the susceptor 16 at which the stagnation of gas is likely to occur is physically excluded. By such a configuration, occurrence of the gas stagnation can be further suppressed, resulting in a high productivity.

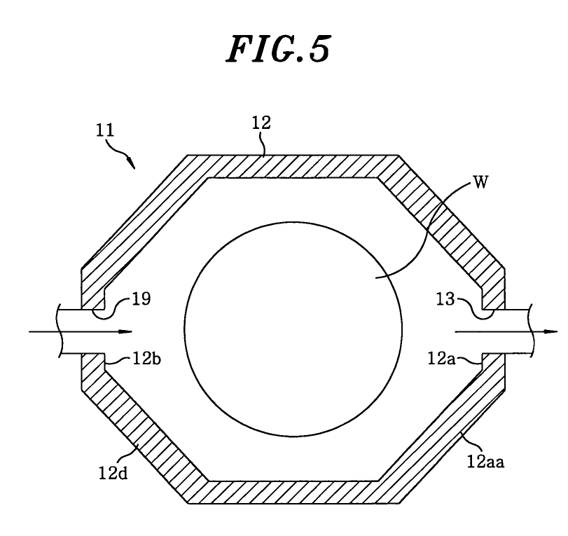

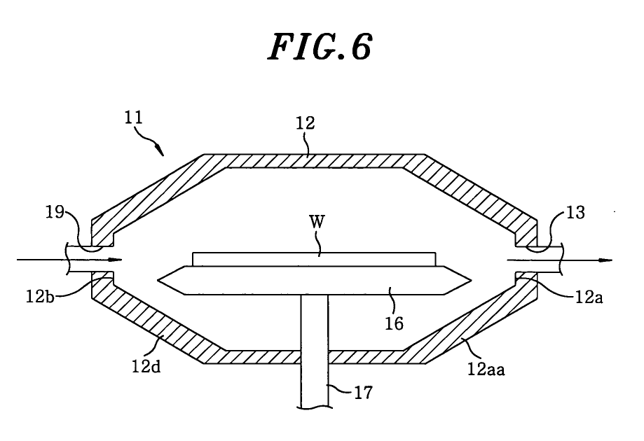

Further, in the above preferred embodiment, the gas is supplied in a direction substantially perpendicular to the main surface of the wafer W. However, the gas may be supplied in a direction substantially parallel to the main surface of the wafer W. In this case, the chamber 12 may be constructed to have an octagonal cross section as viewed in the direction perpendicular to the main surface, as shown in FIG. 5. Alternatively, the chamber 12 may also be constructed to have an octagonal cross section as viewed in the direction parallel to the main surface, as shown in FIG. 6. The chamber 12 may also be constructed by the combination thereof.

As shown in FIGS. 5 and 6, in the substantially vertical cross section and/or the substantially horizontal cross section of the chamber, the sidewall 12d abutting on one surface 12b of the chamber at which the gas supply port 19 is provided is constructed to form an angle greater than 90° with the surface 12b of the chamber 12. Also, at the gas exhaust side, the sidewall 12aa is constructed to form an angle greater than 90° with another surface 12a of the chamber 12 at which the gas exhaust port 13 is provided. That is, regions near the gas supply side and the gas exhaust side at which the stagnation of gas is apt to occur are physically excluded. Further, the gas supplied from the gas supply port 19 flows through a flow passageway with a cross sectional area less than that of a passageway along which the gas flows on the wafer W. As a result, the gas flows at an increased speed along the sidewall 12aa, so that the occurrence of gas stagnation at the gas exhaust side, particularly at locations near the corner portions of the chamber 12 can be effectively suppressed. Accordingly, the changing speed of the gas atmosphere is increased, thereby resulting in a high productivity.

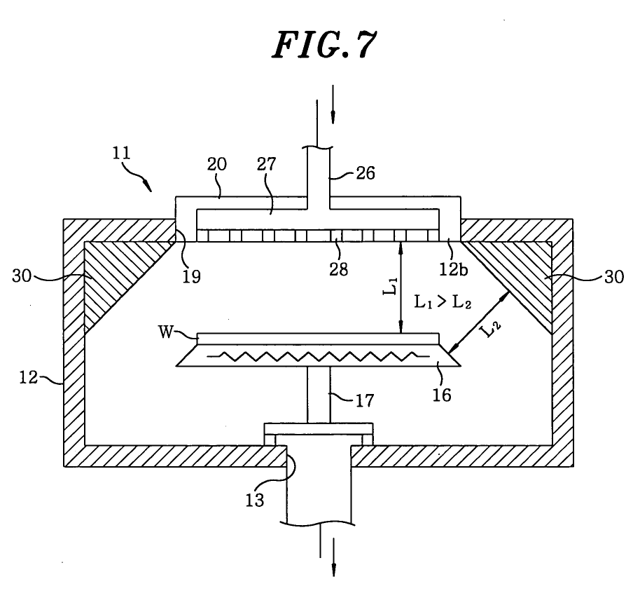

In addition, in the above preferred embodiments, the wall surface of the chamber 12 is constructed to exclude regions at which stagnation of gas is apt to occur. However, different configurations may also be advantageously adopted as long as the gas supply space in the chamber 12 is substantially identical to the above. For example, as shown in FIG. 7, a space filling member 30 may be attached inside the chamber 12. In this case, the member 30 functions similar to the second sidewall 12d. Further, also in such a case, the distance L₂ between the side surface of the susceptor 16 and the member 30 of the chamber 12 is shorter than the distance L₁ between the shower head 20 and the wafer W. That is, after passing through the wafer W, the gas supplied from the shower head 20 flows through a flow passageway with a sectional area less than that of a passageway along which the gas flows on the wafer W.

Furthermore, in the above preferred embodiment shown in FIG. 1, the chamber 12 is constructed to have a substantially hexagonal cross section. However, as long as the gas stagnation regions are excluded in the chamber and a desired conductance can be obtained, the chamber 12 may be constructed to have an arbitrary cross section, e.g., a polygonal shape having six or more faces, an arc shape, a streamline shape or the like.

In the above preferred embodiment, the wafer W is heated by the heater 18 embedded in the susceptor 16; but, the present invention is not limited thereto and the wafer W may be heated by, e.g., an infrared lamp.

In the above preferred embodiment, the Ar gas flows between the supplies of the TiCl₄ gas and the NH₃ gas, to change the atmosphere in the processing area. However, the change of atmosphere may be performed by stopping the supply of the Ar gas and evacuating the chamber 12 to a vacuum state.

In the above preferred embodiment, a TiN film is formed on the wafer W on a monatomic layer basis by using TiCl₄ and NH₃. However, the TiN film formed on the wafer W may be any laminated film made of layers each having a thickness of an atomic layer level and the thickness of one layer is not limited to one monatomic layer.

In the above preferred embodiment, a TiN film is formed on the wafer W by using TiCl₄ and NH₃; but, the substances used in forming the film and the kind of the deposited film are not limited thereto. Besides the TiN film, other metal films of, e.g., Al₂O₃, ZrO₂, TaN, SiO₂, SiN, SiON, WN, WSi and RuO₂ may be formed. Further, In this case, the gas species may be any one of, e.g., TaBr₅, Ta(OC₂H₅)₂, SiCl₄, SiH₄, Si₂H₆, SiH₂Cl₂, WF₆ instead of TiCl₄; and any one of, e.g., N₂, O₂, O₃, NO, N₂O, N₂O₃, N₂O₅ instead of NH₃.

In addition, the purge gas is not limited to Ar, and may be nitrogen, neon and the like as long as it is an inert gas.

The processing device 11 of the present invention may be connected in-line with a processing device for performing another process, e.g., an annealing process, or may be clustered therewith.

It will be understood by those skilled in the art that various changes and modifications may be made without departing from the spirit and scope of the invention. The above-disclosed preferred embodiments have been described for the illustrative purpose and are not intended to limit the scope of the present invention. Accordingly, the scope of the present invention should be defined not by the above description but by the claims and equivalents thereof.

The present application is based on Japanese Patent Application No. 2002-169322 (filed on Jun. 10, 2002) and includes the disclosures of the specification, claims, drawings and abstract thereof. The entire contents of the basic application are incorporated herein by reference.

### INDUSTRIAL APPLICABILITY

The present invention is not limited to the film forming process and can be applied to all processes requiring a process atmosphere to be changed at a high speed by using plural gas species.

Further, the present invention is not limited to a semiconductor wafer and is also applicable to a substrate for use in a liquid crystal display device.

As described above, in accordance with the present invention, there is provided a processing device and method capable of changing a gas atmosphere at a high speed with an increased productivity.

1. A processing device comprising:
a chamber (12) defining a processing area;
a mounting table (16), disposed in the chamber (12), for mounting thereon an object to be processed; and
a gas supply port (19) for supplying a gas into the chamber (12), the gas supply port (19) being provided at a surface (12b) of the chamber (12);
wherein the mounting table (16) is disposed substantially parallel to the surface (12b) of the chamber (12); and
in a substantially vertical cross section of the chamber (12) taken along a flow of the gas from the gas supply port (19) toward the object to be processed, a sidewall (12d) of the chamber (12) defining the processing area and abutting on the surface (12b) of the chamber forms an angle greater than 90° with the surface (12b) of the chamber and extends close to the mounting table 16.

2. The processing device of claim 1, wherein the gas supply port (19) is configured to have a substantially same area as that of the object to be processed.

3. The processing device of claim 1, wherein in a substantially vertical cross section of the mounting table (16) taken along the flow of the gas from the gas supply port (19) toward the object to be processed, a mounting surface on which the object to be processed is mounted forms an angle greater than 90° with a side surface of the mounting table (16) abutting on the mounting surface.

4. The processing device of claim 3, wherein in a substantially vertical cross section of the chamber (12) and the mounting table (16) taken along the flow of the gas from the gas supply port (19) toward the object to be processed, the sidewall (12d) of the chamber is configured to be substantially parallel to the side surface of the mounting table (16).

5. The processing device of claim 4, wherein in a substantially vertical cross section of the chamber (12) and the mounting table (16) taken along the flow of the gas from the gas supply port (19) toward the object to be processed, the distance between the sidewall (12d) of the chamber and the side surface of the mounting table (16) is set to be less than the distance between the surface (12b) of the chamber and the object to be processed.

6. A processing device comprising:
a chamber (12) defining a processing area;
a mounting table (16), disposed in the chamber (12), for mounting thereon an object to be processed; and
a gas supply port (19) for supplying a gas into the chamber (12), the gas supply port (19) being provided at a surface (12b) of the chamber (12);
wherein the mounting table (16) is disposed substantially parallel to a flow direction of the gas supplied from the gas supply port (19); and
in a substantially vertical cross section and/or a substantially horizontal section of the chamber (12), a sidewall (12d) of the chamber (12) defining the processing area and abutting on the surface (12b) of the chamber forms an angle greater than 90° with the surface (12b) of the chamber and extends close to the mounting table 16.

7. A processing device comprising:
a chamber (12) defining a processing area;
a mounting table (16), disposed in the chamber (12), for mounting thereon an object to be processed;
a gas supply port (19) for supplying a gas into the chamber (12), the gas supply port (19) being provided at a surface (12b, 12a) of the chamber (12); and
a gas exhaust port (13) for evacuating the chamber (12);
wherein at least one of sidewalls (12d, 12aa) of the chamber (12) defining the processing area and abutting on one surface (12b, 12a) of the chamber (12) forms an angle greater than 90° with said one surface (12b, 12a) of the chamber (12) and extends close to at least a portion of an outer surface of the object to be processed;
the gas flows a flow passageway whose cross sectional area is gradually increased from the gas supply port (19) to a proximal end of the object to be processed and is gradually decreased from a distal end of the object to be processed to the gas exhaust port (13).

8. (canceled)

9. (canceled)

10. A processing device comprising:
a chamber (12) defining a processing area;
a mounting table (16), disposed in the chamber (12), for mounting thereon an object to be processed; and
a gas supply port (19) for supplying a gas into the chamber (12), the gas supply port (19) being provided at a surface (12b) of the chamber (12);
wherein in a substantially vertical cross section of the chamber (12) taken along a flow of the gas from the gas supply port (19) toward the object to be processed, a sidewall (12d) of the chamber (12) defining the processing area and abutting on the surface (12b) of the chamber extends slant at an angle greater than 90° with respect to the surface (12b) of the chamber to be close to the mounting table 16; and
a side surface of the mounting table 16 is configured to match the slant of the sidewall (12d).
